(19) United States
(12) Patent Application Publication
(10) Pub. No.: US 2008/0142195 A1
(43) Pub. Date: Jun. 19, 2008

(54) Active condensation enhancement for alternate working fluids

(76) Inventors: Hakan Erturk, Phoenix, AZ (US); Ioan Sauciuc, Phoenix, AZ (US)

Correspondence Address: TROP PRUNER & HU, PC, 1616 S. VOSS ROAD, SUITE 750, HOUSTON, TX, 77057-2631, US

(21) Appl. No.: 11/638,859

(22) Filed: Dec. 14, 2006

(51) Int. Cl. H01L 23/427; F28D 15/02

(52) U.S. Cl. 165/94

(57) ABSTRACT

A vapor chamber used for cooling an electronic component may have an evaporation surface and a condensation surface. A moving device may be provided to sweep condensed liquid from the condensation surface. Particularly, with alternate working fluids such as hydrofluoroethers, where the condensation resistance is a substantial portion of the overall resistance of the system, performance of the system may be dramatically improved through active condensation enhancement.

### BACKGROUND

This relates generally to vapor chambers for use in cooling electronic components.

Electronic components generate heat during operation. Ideally, that heat may be dissipated in passive fashion. By passive, it is intended to refer to heat dissipation without a pump, compressor, or fluid moving device other than a fan. For example, the use of a heat sink of thinned heat exchanger is a passive technique for removing heat. This passivity is advantageous since no power is needed to implement the transfer and there may be less reliability concerns.

Unfortunately, in some cases, passive techniques are insufficient for many advanced heat generating semiconductor technologies such as microprocessors. Because of the amount of heat generated, the relatively small spaces involved and the relatively small size of the components, cooling may become a more complex issue.

The hotter that the electronic component becomes during operation, the less efficiently it continues to operate. Thus, not only may it operate more slowly, but the component may also operate less efficiently from an energy consumption standpoint.

### BRIEF DESCRIPTION OF THE DRAWINGS

FIG. 1 is an enlarged, cross-sectional view of one embodiment of the present invention;

FIG. 2 is an enlarged cross-sectional view taken generally along the line 2-2 in FIG. 1; and

FIG. 3 is a system depiction for one embodiment.

### DETAILED DESCRIPTION

In accordance with some embodiments of the present invention, a vapor chamber may be utilized with what is called an alternate working fluid. Fluid is considered an alternate working fluid because it is an alternative to existing perfluorinated compounds. Unfortunately, perfluorocarbons have high global warming potentials and hydrofluorocarbons are being eliminated in many parts of the world because of their contribution to global warming. Thus, alternative chemistries, such as perfluorinated materials that do not create global warming adverse effects, are considered alternative working fluids. The most promising of these are the segregated hydrofluoroethers.

One problem with segregated hydrofluoroethers is that while they have relatively good evaporator performance, they have relatively poor condensation performance. Evaporation resistance indicates the temperature difference caused by transferring a unit of heat. Thus, using hydrofluoroethers may be advantageous compared to some working fluids, such as water, but their efficiencies are still somewhat insufficient because of their poor condensation resistance.

Particularly in cases where the alternate working fluid is one which has a condensation resistance that constitutes more than 50 percent of the resistance of the overall system, there is a need for ways to reduce the degradation of condensation performance so that these alternate working fluids may improve evaporation resistance, while still providing acceptable environmental effects.

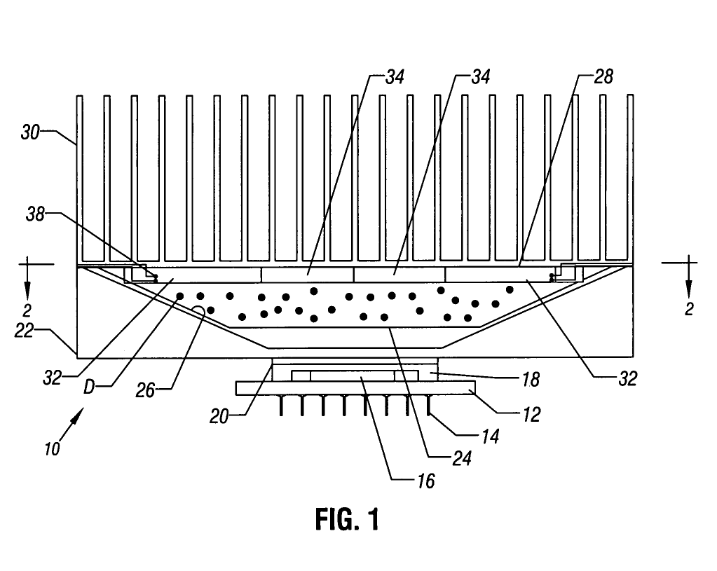

Referring to FIG. 1, a vapor chamber 10 may include a substrate 12 from which a plurality of pins 14 depend. These depending pins 14 may be replaced with any other contact, including solder balls, springs, or the like. The substrate 12 supports an integrated circuit 16 which may be secured to a substrate through suitable contacts such as pins, sockets, solder balls, and springs, to mention a few examples. Over the integrated circuit 16 may be a heat spreader 18. The heat spreader is covered on its upper surface by a thermal interface material 20 for providing good thermal conduction to a vapor chamber 22 positioned thereover.

The vapor chamber 22 includes a boiling surface 24. In some embodiments, the boiling surface may be plasma sprayed, microporous boiling surface. See, for example, Tehver, J., et al. “Heat Transfer and Hysteresis Phenomena in Boiling on Porous Plasma-sprayed Surface,” Experimental Thermal and Fluid Science, volume 5, 1992, pp. 714-727.

The combination of the plasma sprayed microporous boiling enhancement surface and the use of relatively low evaporation resistance, alternate working fluids, such as segregated hydroethers, results in a situation where the evaporator resistance decreases significantly and condenser resistance increases so that condenser resistance becomes more than half of the overall resistance of the vapor chamber 22.

The vapor chamber interior may be defined by angled side walls 26. These inclined side walls help fluid return to the evaporator and prevent sub-cooling in dead zones. Thus, fluid evaporated from the evaporator may condense on the condensation surface 28 at the upper side of the vapor chamber. The condensation surface 28 may be thermally coupled to a finned heat exchanger 30. Other heat exchanger designs may be utilized as well including thermoelectric coolers. These heat exchangers may be passive or active heat exchangers.

The efficiency of the overall vapor chamber 22 may be improved by decreasing the condensation resistance. The condensation resistance with alternate working fluids may be reduced by using a system that decreases the thickness of the liquid film on the condensation surface 28. Specifically, in the process of condensation, particularly with alternate working fluids, such as hydrofluoroethers, a a condensed liquid film thickness builds up on the condensation surface and introduces a thermal resistance across the thickness of the film due to the thermal conductivity of the fluid.

The surface tension of the segregated hydrofluoro-ethers is relatively low, leading to film-wise condensation which has an order of magnitude lower performance than drop-wise condensation. In addition, due to the low latent heat of the fluid, the condensate film is relatively thicker and the thicker liquid film, together with the relatively low thermal conductivity of the fluid, acts as an insulator.

In order to reduce the film thickness and, therefore, the condensation resistance, the film may be periodically wiped using a mechanism to simply remove the condensed liquid. The wiped, condensed liquid then falls as droplets D back to the evaporation surface.

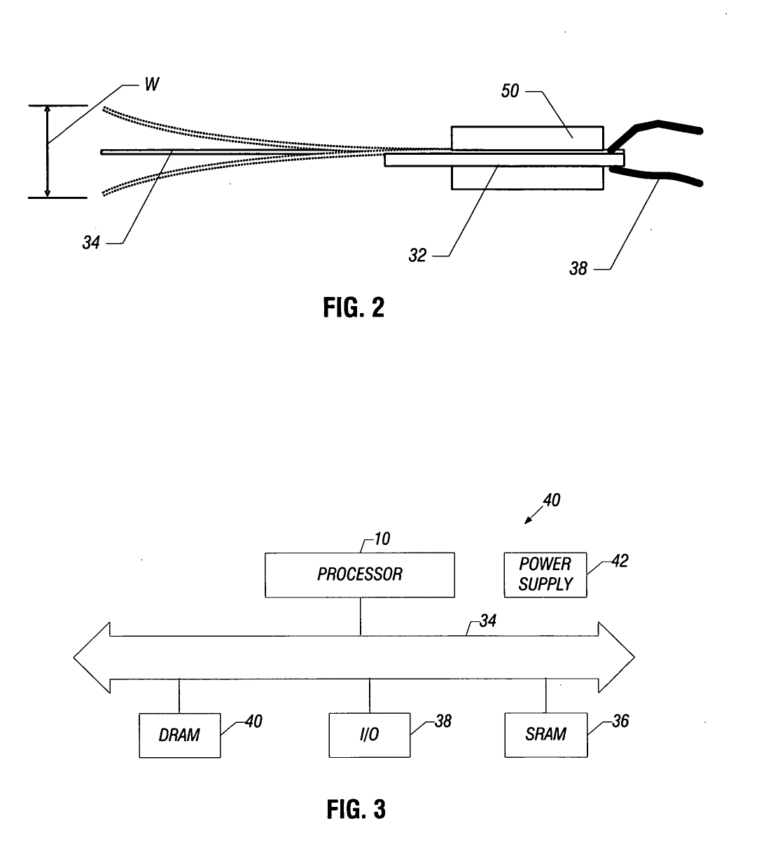

Various mechanisms may be utilized for this purpose, including a piezoelectric actuator. The piezoelectric actuator, in one embodiment, may include a patch 32 on one side, a patch 32 on the opposite side, and blades 34 in between and connected to one of the patches 32. The piezoelectric operation of the blades 34 causes them to flex and rotate through a sweeping arc W across the condensation surface 28, removing the liquid therefrom and returning it as droplets to the evaporation surface as shown in FIG. 2. A hold jig 50 may hold a blade on the condensation surface 28.

Electrical power may be supplied to the piezoelectric actuators by lines 38. Thus, a small amount of electric power may be consumed. Since the chamber operates in a vacuum in one embodiment, that power may be transferred wirelessly to the piezoelectric actuator, in one embodiment. Otherwise, the wire passages may be sealed.

Other systems for removing the condensed liquid may also be used, including microelectromechanical actuators, electroosmotic operators, and other low power consuming moving devices.

The periodicity of the wiping action W may be set to a desired operating point and may be continuous so long as the system is operating. However, in other embodiments, sensors may be utilized, controlled in some cases by the electronic circuit being cooled, to adjust the wiping action, based on either the performance of the vapor chamber 22 or the operating conditions of the electronic component, to mention two examples. For example, in some cases based on the loads on the electronic circuit, its time of operation or even its current temperature, the efficiency of the system may be increased by increasing the rapidity of the wiping action or, when no longer needed, to save power, may be reduced. For example, a feedback controller may monitor noise, power consumption of the cooled component, and temperatures on the hot and cold ends of the vapor chamber.

In some cases, the wiping action need not actually touch the evaporation surface since all that is needed is to reduce the thickness of the condensed liquid. This reduction in thickness decreases the condensation resistance.

It is desired that the condensation resistance be decreased below 0.10° C. per Watt with a 50 micron liquid thickness and, particularly, it is desirable that the condensation thickness be below 0.05° C. per Watt and, most advantageous, approximately 0.01° C. per Watt.

In some embodiments, the piezoelectric system may consume minimal power. For example, power consumption on the order of milli-Watts may be achieved. The wiring may be embedded in the base of the heat sink 30 in some cases.

Thus, particularly where the condensation resistance is a substantial portion of the overall resistance of the system, active condensation enhancement techniques may dramatically improve system heat transfer performance with minimal power consumption.

In some embodiments, a similar wiping action may be applied to the evaporation surface to reduce bubbling on the evaporation surface.

Referring to FIG. 3, in accordance with some embodiments of the present invention, a computer system 40 may be formed using the vapor chamber 10 and integrated circuit 16 shown in FIG. 1. Particularly, the circuit 16 may be a processor and may be coupled by a bus 34 to various other components such as dynamic random access memory (DRAM) 40, input/output (I/O) devices 38, and static random access memory (SRAM) 36. A suitable power supply 42 may supply power to the processor 10.

In some embodiments of the present invention, any processor-based system may be formed. Thus, the embodiment shown in FIG. 3 is merely an example.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. a method comprising:
providing a moving element to remove condensed fluid from a condensation surface of a vapor chamber.

2. The method of claim 1 including moving said element using a piezoelectric actuator.

3. The method of claim 1 including providing an alternate working fluid in said chamber.

4. The method of claim 1 including providing hydrofluoroether to said chamber.

5. The method of claim 1 including using a working fluid that results in a condensation resistance being more than 50% of the resistance of the fluid system without moving said moving element.

6. The method of claim 1 including securing an integrated circuit to said vapor chamber.

7. The method of claim 6 including controlling the movement of said moving element based at least in part on the load on said integrated circuit.

8. The method of claim 1 including providing a plasma sprayed microporous boiling enhancement surface in said chamber.

9. The method of claim 8 including forming said chamber with inclined walls to transfer condensed fluid to said enhancement surface.

10. The method of claim 1 including providing a pair of moving elements that move in arcs across said condensation surface.

11. A vapor chamber comprising:
an evaporation surface;
a condensation surface;
a sealed space between said evaporation and condensation surfaces; and
a moving element to remove condensate from said condensation surface.

12. The chamber of claim 11 including an alternate working fluid.

13. The chamber of claim 11 including hydrofluoroether.

14. The chamber of claim 11 wherein a condensation resistance without the moving element operating is more than 50% of the chamber resistance.

15. The chamber of claim 11 including a piezoelectric actuator to move said element.

16. The chamber of claim 15 including using a wireless link to supply power to said operation.

17. The chamber of claim 11 including a microcontroller to control the operation of said element.

18. The chamber of claim 17 wherein said microcontroller to control the element based at least in part on the load on an object thermally coupled to said condensation surface.

19. The chamber of claim 11 including inclined walls to carry condensed fluid to said evaporation surface.

20. The chamber of claim 11 wherein said evaporation surface has a plasma sprayed microporous boiling enhancement surface.

21. The chamber of claim 11 including a pair of moving elements that move in an arcuate fashion across said condensation surface.

22. An electronic component comprising:
an integrated circuit; and
a vapor chamber secured to said circuit, said vapor chamber including:
an evaporation surface;
a condensation surface;
a sealed space between said evaporation and condensation surfaces; and
a moving element to remove condensate from said condensation surface.

23. The component of claim 22 including an alternate working fluid.

24. The component of claim 22 including hydrofluoroether.

25. The component of claim 22 wherein a condensation resistance without the moving elements operating is more than 50% of the chamber resistance.

26. The component of claim 22 wherein said circuit is a microprocessor.

27. A system comprising:
a processor including a vapor chamber, said vapor chamber including:
an evaporation surface;
a condensation surface;
a sealed space between said evaporation and condensation surfaces;
a moving element to remove condensate from said condensation surface; and
a dynamic random access memory coupled to said processor.

28. The system of claim 27 including an alternate working fluid.

29. The system of claim 27 including hydrofluoroether.

30. The system of claim 27 wherein a condensation resistance without the moving elements operating is more than 50% of the chamber resistance.
